(19) United States
(12) Patent Application Publication
(10) Pub. No.: US 2026/0324258 A1
(43) Pub. Date: Oct. 15, 2026

(54) Display Device, Electric Device Including The Same, And Method of Manufacturing Display Device

(71) Applicant: Samsung Display Co., Ltd., Yongin-si (KR)

(72) Inventors: Kyumin Kim, Yongin-si (KR); Ho-Yong Shin, Yongin-si (KR); Seoyoon Yoo, Yongin-si (KR); Jemin Lee, Yongin-si (KR); Cheol Min Lee, Yongin-si (KR); Junhwi Lim, Yongin-si (KR)

(73) Assignee: Samsung Display Co., Ltd., Yongin-si (KR)

(21) Appl. No.: 19/630,693

(22) Filed: Mar. 27, 2026

(30) Foreign Application Priority Data
Apr. 15, 2025 (KR) 10-2025-0048972

(51) Int. Cl. H10K 59/80; H10K 59/12

(52) U.S. Cl. CPC H10K 59/873; H10K 59/1201; H10K 59/80518; H10K 59/878

(57) ABSTRACT

A display device includes a substrate including an open area, a display area at least partially surrounding the open area, and a first non-display area between the open area and the display area, a plurality of display elements in the display area, each including a pixel electrode, a counter electrode, and an intermediate layer between the pixel electrode and the counter electrode, an organic layer in the first non-display area, and a first groove surrounding the open area, wherein the first groove includes a first hole in the organic layer. The first groove includes a mesa structure within the first hole, and a reflective layer on the mesa structure. An electronic device may include the display device.

### CROSS-REFERENCE TO RELATED APPLICATION

This application claims priority under 35 U.S.C. §119 to Korean Patent Application No. 10-2025-0048972, filed on April 15, 2025, in the Korean Intellectual Property Office, the disclosure of which is incorporated by reference herein in its entirety.

### TECHNICAL FIELD

Aspects of the present disclosure relate to a display device, an electronic device including the same, and a method of manufacturing the display device.

### BACKGROUND

Display devices are devices that visually display data. These display devices include a substrate divided into a display area and a non-display area. A plurality of pixel areas are defined in the display area. In addition, a thin-film transistor and a pixel electrode electrically connected to the thin-film transistor are provided in the display area for each of the pixel areas.

The applications of display devices have been diversified in recent years. In addition, as the display devices become thinner and lighter, the ranges of use of the display devices have become more widespread. With the increasing area occupied by a display area in the display device, various functions are being integrated with or associated with the display device. As an approach to adding various functions while increasing the display area, a display device in which an opening is formed in the display area has been proposed.

Meanwhile, in the case of a display device having an opening area, foreign substances such as moisture may penetrate through side surfaces of the opening. In such a case, a problem may arise in that display elements that at least partially surround the opening may be damaged.

### SUMMARY

Aspects of the present disclosure are directed to addressing the above-described problems, and provide a display device capable of preventing moisture permeation, and an electronic device including the same. However, the above objective is exemplary, and the scope of the present disclosure is not limited thereto.

According to an aspect of the present disclosure, there is provided a display device including a substrate including an opening area, a display area at least partially surrounding the opening area, and a first non-display area positioned between the opening area and the display area, a plurality of display elements disposed in the display area, each including a pixel electrode, a counter electrode, and an intermediate layer positioned between the pixel electrode and the counter electrode, an organic pattern layer disposed in the first non-display area, and a first groove defined by a first hole of the organic pattern layer and surrounding the opening area, wherein the first groove includes a mesa structure disposed within the first hole, and a reflective layer disposed on the mesa structure.

In an aspect of the present disclosure, the mesa structure may have a shape protruding in a stacking direction, and include an upper surface and side surfaces, both covered with the reflective layer.

In an aspect of the present disclosure, the mesa structure may include inclined surfaces inclined such that a width of the mesa structure becomes narrower in an upward direction.

In an aspect of the present disclosure, the mesa structure may include a same material as an organic insulating layer disposed in the display area.

In an aspect of the present disclosure, the organic pattern layer may include inner sidewalls formed on opposite sides of the mesa structure, and the inner sidewalls may be formed to be spaced apart from the reflective layer.

In an aspect of the present disclosure, the organic pattern layer may include a positive-type photoresist.

In an aspect of the present disclosure, the organic pattern layer may include first protruding tips protruding toward a center of the first hole.

In an aspect of the present disclosure, the reflective layer and the pixel electrode may include a same material.

In an aspect of the present disclosure, at least one layer among a plurality of layers included in the intermediate layer may be disconnected by the first groove.

In an aspect of the present disclosure, the intermediate layer may be disposed on an upper surface of the organic pattern layer and on the reflective layer.

In an aspect of the present disclosure, the display device may further include a metal oxide layer disposed on the reflective layer and on the organic pattern layer.

In an aspect of the present disclosure, the metal oxide layer may include a second hole overlapping the first hole.

In an aspect of the present disclosure, the metal oxide layer may include second protruding tips protruding toward a center of the second hole.

According to another aspect of the present disclosure, there is provided a method of manufacturing a display device, the method including forming a circuit layer including an inorganic insulating layer on a substrate, the substrate including an opening area, a display area at least partially surrounding the opening area, and a first non-display area positioned between the opening area and the display area, forming an organic insulating layer on the inorganic insulating layer, forming a mesa structure by removing at least a portion of the organic insulating layer in the first non-display area, forming a reflective layer on the mesa structure, forming an organic pattern layer on the organic insulating layer and on the reflective layer, exposing a portion of the organic pattern layer overlapping the mesa structure, and forming protruding tips by removing the exposed portion of the organic pattern layer.

In an aspect of the present disclosure, the organic pattern layer may include a positive-type photoresist.

In an aspect of the present disclosure, the reflective layer may include a same material as a pixel electrode of the display area.

In an aspect of the present disclosure, the exposing of the portion of the organic pattern layer may include exposing inner sidewalls of the organic pattern layer adjacent to the mesa structure using light reflected from side surfaces of the mesa structure.

In an aspect of the present disclosure, the forming of the protruding tips may include forming a metal oxide layer on the organic pattern layer and on the reflective layer.

In an aspect of the present disclosure, the forming of the protruding tips may include forming second protruding tips from a metal oxide layer disposed on the organic pattern layer, by partially removing inner sidewalls of the organic pattern layer through an ashing process.

According to another aspect of the present disclosure, there is provided an electronic device including an input module configured to receive commands or data for use in the electronic device from an external source, a processor configured to process input data received from the input module and to output image data or command data, and a display device configured to implement one or more images by the processor, wherein the display device includes a substrate including an opening area, a display area at least partially surrounding the opening area, and a first non-display area positioned between the opening area and the display area, a plurality of display elements disposed in the display area, each including a pixel electrode, a counter electrode, and an intermediate layer positioned between the pixel electrode and the counter electrode, an organic pattern layer disposed in the first non-display area, and a first groove defined by a first hole of the organic pattern layer and surrounding the opening area, wherein the first groove includes a mesa structure disposed within the first hole, and a reflective layer disposed on the mesa structure.

### BRIEF DESCRIPTION OF THE DRAWINGS

The above and other features and advantages of certain aspects of the disclosure will be more apparent from the following description taken in conjunction with the accompanying drawings in which:

FIG. 1 is a perspective view schematically illustrating a display device according to an aspect of the present disclosure;

FIGS. 2A and 2B are cross-sectional views schematically illustrating a cross section taken along line I-I′ of FIG. 1;

FIG. 3 is a plan view schematically illustrating a display panel according to an aspect of the present disclosure;

FIG. 4 is a circuit diagram schematically illustrating a display element included in one pixel of the display device according to an aspect of the present disclosure, and a pixel circuit connected to the display element;

FIG. 5 is a plan view schematically illustrating a portion of a display panel according to an aspect of the present disclosure;

FIG. 6 is a cross-sectional view schematically illustrating a cross section taken along line II-II′ of FIG. 5;

FIG. 7 is a cross-sectional view of a display area shown in FIG. 6;

FIG. 8 is an enlarged cross-sectional view illustrating a second groove of FIG. 6;

FIGS. 9 to 12 are cross-sectional views schematically illustrating some operations of a method of manufacturing the display panel according to an aspect of the present disclosure;

FIGS. 13 to 15 are cross-sectional views schematically illustrating sequential steps of a method of manufacturing the display panel according to an aspect of the present disclosure;

FIG. 16 is a block diagram of an electronic device according to an aspect of the present disclosure; and

FIG. 17 illustrates schematic views of electronic devices according to various aspects of the present disclosure.

### DETAILED DESCRIPTION

While the technical features of the present disclosure are susceptible to various modifications and alternative forms, specific aspects thereof are shown by way of example in the drawings and will herein be described in detail. Advantages and features of the present disclosure and methods for accomplishing the same will be more clearly understood from aspects described below with reference to the drawings. However, the present disclosure is not limited to the aspects disclosed below but may be implemented in various forms.

In the following aspects, the terms “first,” “second,” and the like have been used to distinguish one component from another, rather than limitative in all aspects.

In the following aspects, singular forms are intended to include plural forms as well, unless the context clearly indicates otherwise.

It will be further understood that the terms “including” and/or “having” used herein specify the presence of stated features or components, but do not preclude the presence or addition of one or more other features or components.

In the following aspects, when a unit, region, or component is referred to as being “formed on” another unit, region, or component, it can be directly or indirectly formed on the other unit, region, or component. That is, for example, intervening units, regions, or components may be present.

In the following aspects, terms such as “connecting” or “coupling” two members do not necessarily mean a direct and/or fixed connection or coupling of the two members, unless the context clearly indicates otherwise, and do not preclude another members from being positioned between the two members.

Sizes of components in the drawings may be exaggerated or reduced for convenience of description. For example, the size and/or thickness of each component shown in the drawings are arbitrarily represented for convenience of description, and thus, the present disclosure is not necessarily limited thereto.

The phrase “a region/portion corresponds to a region/portion,” means that the region/portion overlaps the region/portion, and the regions/portions may not be limited to having the same area and/or the same shape.

Hereinafter, the aspects of the present disclosure will be described below in detail with reference to the accompanying drawings, and when the aspects of the present disclosure are described with reference to the drawings, the same or corresponding components are given the same reference numerals, and repetitive descriptions thereof will be omitted.

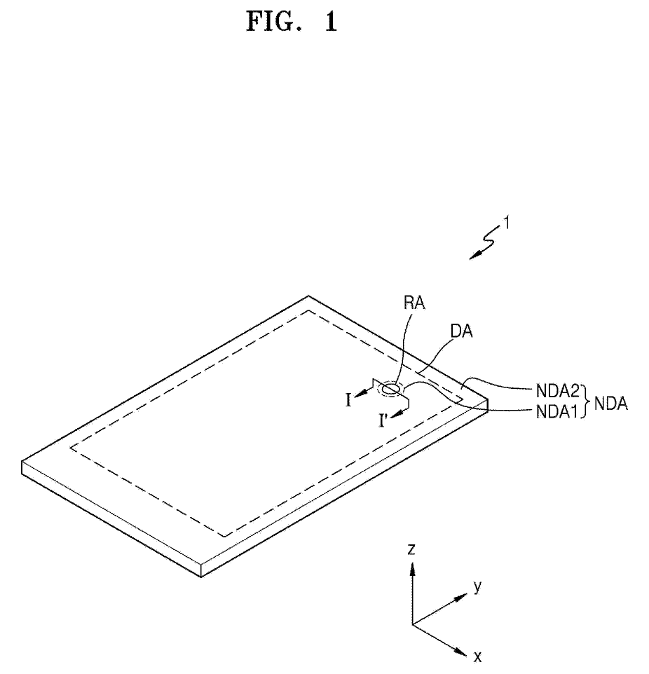

FIG. 1 is a perspective view schematically illustrating a display device according to an aspect of the present disclosure.

The display device according to an aspect of the present disclosure may include a display surface defined by a first direction corresponding to an X-axis direction and a second direction corresponding to a Y-axis direction. Through the display surface, images generated by the display device may be provided to a user.

Hereinafter, a direction that intersects substantially perpendicularly with a plane defined by the first direction and the second direction is referred to as a third direction. The third direction serves as a reference for distinguishing a front surface (top surface) and a rear surface (bottom surface) of each member. In the present specification, the term “on the plane” may be defined as a state when viewed in the third direction.

In the drawings, a display area DA is illustrated as having a substantially rectangular shape, but the present disclosure is not limited thereto. The display area DA may be provided in various shapes, such as a circular shape, an elliptical shape, or a polygonal shape.

The display area DA is a portion that displays images, and a plurality of pixels P may be disposed in the display area DA. Hereinafter, the term “pixel” in the present specification may refer to a “sub-pixel.” Each of the pixels P may include an organic light-emitting diode OLED as a light-emitting element. Each of the pixels P may emit light of, for example, a red, green, blue, or white color.

Referring to FIG. 1, a display device 1 includes the display area DA that emits light and a non-display area NDA that does not emit light. The display device 1 may provide a predetermined image using light emitted from the plurality of pixels disposed in the display area DA. The display device 1 includes an opening area RA that is at least partially surrounded by the display area DA. FIG. 1 illustrates an example in which the opening area RA is entirely surrounded by the display area DA. The non-display area NDA may include a first non-display area NDA1 that surrounds the opening area RA, and a second non-display area NDA2 that surrounds an outer periphery of the display area DA. The first non-display area NDA1 may entirely surround the opening area RA, the display area DA may entirely surround the first non-display area NDA1, and the second non-display area NDA2 may entirely surround the display area DA.

Hereinafter, an organic light-emitting display device will be described as an example of the display device 1 according to an aspect of the present disclosure. However, the display device 1 according to an aspect of the present disclosure is not limited thereto. The display device 1 according to an aspect may be a display device such as an inorganic light-emitting display device (also referred to as an inorganic EL display device), or a quantum dot light-emitting display device. For example, a light-emitting layer included in a light-emitting element provided in the display device 1 may include an organic material or an inorganic material. In addition, quantum dots may be located in a path of light emitted from the light-emitting layer.

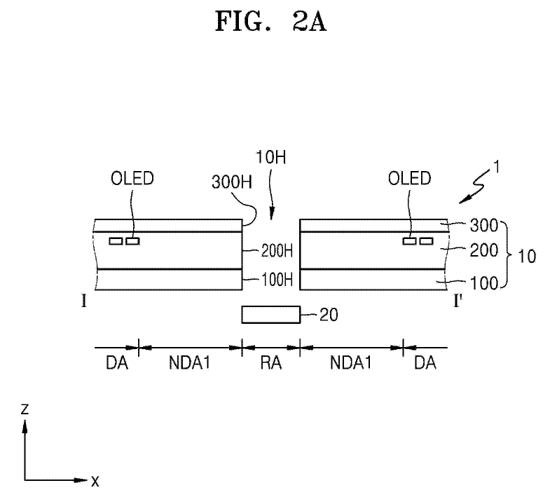

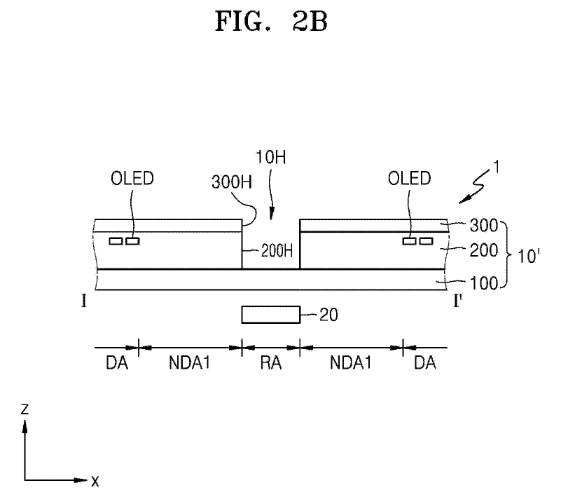

FIGS. 2A and 2B are cross-sectional views schematically illustrating a cross section taken along line I-I′ of FIG. 1.

Referring to FIG. 2A, the display device 1 may include a display panel 10, and an electronic element 20 corresponding to the opening area RA of the display panel 10. Although not shown in the drawings, additional component(s) such as an input sensing member for detecting touch input, an anti-reflection member including a polarizer and a retarder or a color filter and a black matrix, and a transparent window may be further disposed on the display panel 10.

The display panel 10 may include a substrate 100, a display element layer 200 disposed on the substrate 100 and including display elements, and a thin-film encapsulation layer 300 as an encapsulation member that covers the display element layer 200.

The substrate 100 may include an insulating material such as glass, quartz, or a polymer resin. The substrate 100 may be a rigid substrate or a flexible substrate that may be bendable, foldable, or rollable. For example, the substrate 100 may include a polymer resin such as polyethersulfone, polyacrylate, polyetherimide, polyethylene naphthalate, polyethylene terephthalate, polyphenylene sulfide, polyarylate, polyimide, polycarbonate, or cellulose acetate propionate. The substrate 100 may have a multilayer structure including a layer containing the above-described polymer resin and an inorganic layer (not shown).

The display element layer 200 includes display elements such as organic light-emitting diodes OLED that are disposed in the display area DA. Although not shown in the drawings, the display element layer 200 may further include circuits and lines that are electrically connected to the organic light-emitting diodes OLED, which serve as display elements. The thin-film encapsulation layer 300 covers the display element layer 200, thereby preventing moisture or contaminants from penetrating into the display element layer 200 from the outside. The thin-film encapsulation layer 300 may include at least one inorganic encapsulation layer and at least one organic encapsulation layer.

As illustrated in FIG. 2A, the display panel 10 may include an opening 10H that corresponds to the opening area RA and passes through the display panel 10. The substrate 100, the display element layer 200, and the thin-film encapsulation layer 300 may respectively include a first opening 100H, a second opening 200H, and a third opening 300H corresponding to the opening area RA, and the first to third openings 100H, 200H, and 300H may form the opening 10H of the display panel 10.

The opening area RA is a position in which the electronic element 20 is disposed, and the electronic element 20 may be disposed to correspond to the first to third openings 100H, 200H, and 300H of the substrate 100, the display element layer 200, and the thin-film encapsulation layer 300. The first opening 100H may be formed to pass through from an upper surface to a lower surface of the substrate 100, the second opening 200H may be formed to pass through from a lowest layer to a topmost layer of the display element layer 200, and the third opening 300H may be formed to pass through the thin-film encapsulation layer 300.

The electronic element 20 may be an electronic element that utilizes light or sound. For example, the electronic element may include a sensor that receives and uses light, such as an infrared sensor, a camera that receives light to capture an image, a sensor that outputs and detects light or sound to measure a distance or to recognize a fingerprint or the like, a miniature lamp that emits light, a speaker that outputs sound, and the like. An electronic element that utilizes light may use light in various wavelength ranges, such as visible, infrared, or ultraviolet light. The opening area RA corresponds to a transmission area through which light and/or sound may be transmitted, either by being emitted from the electronic element 20 to the outside or by being propagated from the outside toward the electronic element 20. As shown in FIG. 2A, when a portion of the display panel 10 corresponding to the opening area RA is entirely removed, for example, when the opening 10H passes through the display panel 10, light or sound emitted from or received by the electronic element 20 may be utilized more effectively.

Although FIG. 2A illustrates an example in which the electronic element 20 is disposed below the substrate 100, the present disclosure is not limited thereto. In another aspect, the electronic element 20 may be located within the opening 10H of the display panel 10.

Referring to FIG. 2B, the substrate 100 may not include the first opening 100H, unlike FIG. 2A, in which the substrate 100, the display element layer 200, and the thin-film encapsulation layer 300 respectively include the first to third openings 100H, 200H, and 300H corresponding to the opening area RA.

Referring to FIG. 2B, although the substrate 100 does not include the first opening, the display element layer 200 and the thin-film encapsulation layer 300 respectively include the second and third openings 200H and 300H, thereby securing light transmittance for use by the electronic element 20. In an aspect, the light transmittance of the opening area RA in the display panel 10 illustrated in FIG. 2B may be about 50% or more, and preferably 70% or more, such as 75%, 80%, 85%, or 90% or more.

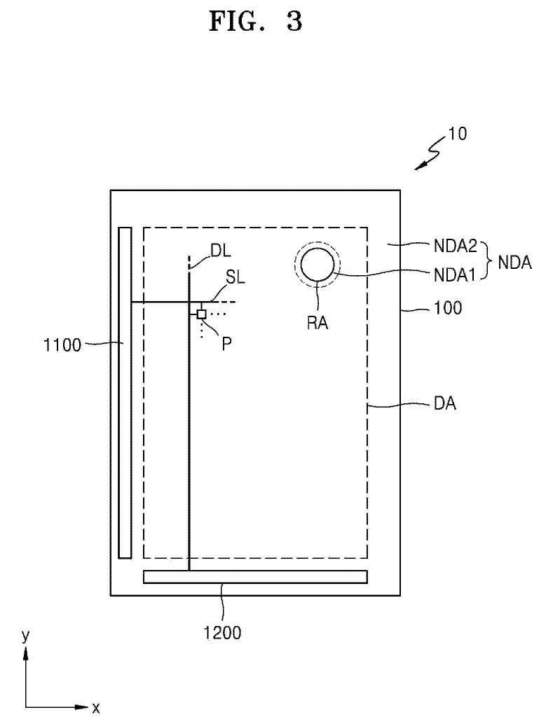

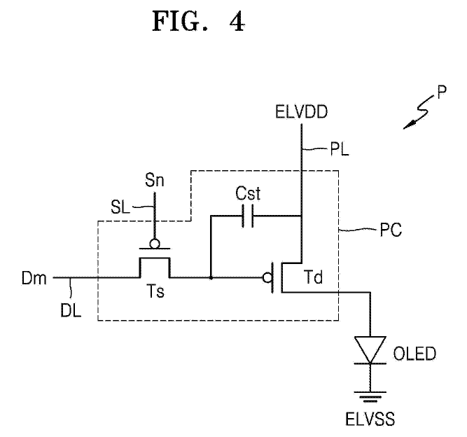

FIG. 3 is a plan view schematically illustrating a display panel according to an aspect of the present disclosure, and FIG. 4 is a circuit diagram schematically illustrating a display element included in one pixel of the display device according to an aspect of the present disclosure, and a pixel circuit connected to the display element.

Referring to FIG. 3, the display panel 10 includes a plurality of pixels P disposed in the display area DA. Each of the pixels P may include an organic light-emitting diode OLED. Each of the pixels P may emit light of, for example, a red, green, blue, or white color through the organic light-emitting diode.

The first non-display area NDA1 surrounds the opening area RA. The first non-display area NDA1 is an area in which display elements such as organic light-emitting diodes that emit light are not disposed, and signal lines that provide a signal to the pixels P provided around the opening area RA may pass across, or groove(s), which will be described below, may be disposed in the first non-display area NDA1 In the second non-display area NDA2, components such as a scan driver (not shown) configured to supply a scan signal to each pixel P, a data driver (not shown) configured to supply a data signal to each pixel P, and main power lines (not shown) configured to supply first and second power voltages may be disposed.

FIG. 3 may be understood as a view of the substrate 100 in the display panel 10. For example, the substrate 100 may be understood as including the opening area RA, the display area DA, and the first and second non-display areas NDA1 and NDA2.

Referring to FIG. 4, each of the pixels P may include a pixel circuit PC connected to a scan line SL and a data line DL, and an organic light-emitting diode OLED as a display element which is connected to the pixel circuit PC.

The pixel circuit PC may include a driving thin-film transistor Td, a switching thin-film transistor Ts, and a storage capacitor Cst. The switching thin-film transistor Ts is connected to the scan line SL and the data line DL, and may transfer a data signal Dm input through the data line DL to the driving thin-film transistor Td in response to a scan signal Sn input through the scan line SL.

The storage capacitor Cst is connected to the switching thin-film transistor Ts and a drive voltage line PL, and may store a voltage corresponding to a difference between a voltage transmitted from the switching thin-film transistor Ts and a first power voltage ELVDD or drive voltage supplied through the drive voltage line PL.

The driving thin-film transistor Td is connected to the drive voltage line PL and the storage capacitor Cst, and may control a drive current flowing from the drive voltage line PL to the organic light-emitting diode OLED in response to a voltage value stored in the storage capacitor Cst. The organic light-emitting diode OLED may emit light having a predetermined luminance according to the drive current.

Although FIG. 4 illustrates an aspect in which the pixel circuit PC includes two thin-film transistors and one storage capacitor, the present disclosure is not limited thereto. In another aspect, the pixel circuit PC may include, for example, seven thin-film transistors and one storage capacitor. In another aspect, the pixel circuit PC may include two or more storage capacitors.

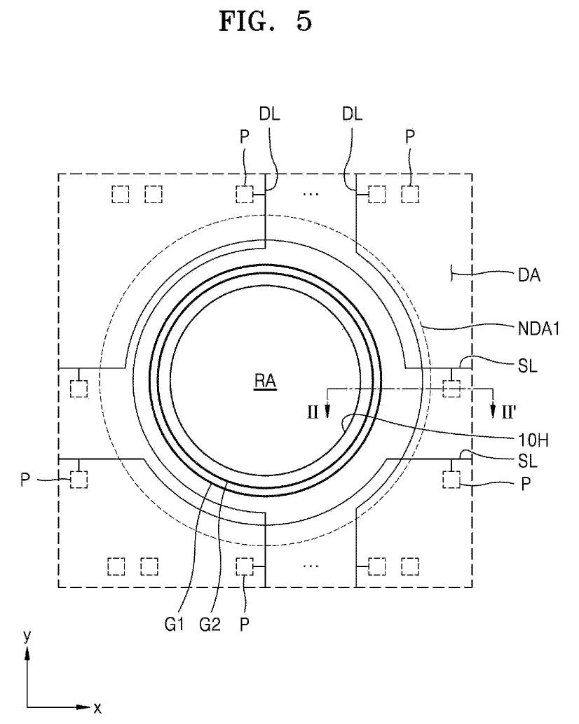

FIG. 5 is a plan view schematically illustrating a portion of the display panel according to an aspect of the present disclosure. FIG. 5 illustrates signal lines and grooves located in the first non-display area.

Referring to FIG. 5, the pixels P are disposed around the opening area RA in the display area DA, and the first non-display area NDA1 may be located between the opening area RA and the display area DA.

The pixels P may be disposed to be spaced apart from each other around the opening area RA. The pixels P may be disposed spaced apart above and below the opening area RA, or to the left and right of the opening area RA.

Signal lines that are adjacent to the opening area RA among signal lines that supply signals to the pixels P may detour around the opening area RA. Some data lines DL among data lines DL that pass across the display area DA may extend in a y-direction, provide a data signal to the pixels P disposed along the y-direction with the opening area RA therebetween, and detour along an edge of the opening area RA in the first non-display area NDA1. Some scan lines SL among scan lines SL that pass across the display area DA may extend in an x-direction, provide a scan signal to the pixels P disposed along the x-direction with the opening area RA therebetween, and detour along an edge of the opening area RA in the first non-display area NDA1.

Grooves may be located between the opening area RA and the display area DA. In this regard, FIG. 5 illustrates an example in which first and second grooves G1 and G2 are located between the opening area RA and the display area DA. However, the scope of the present disclosure is not limited thereto, and additional grooves other than the first and second grooves G1 and G2 may further be included.

The first and second grooves G1 and G2 may each have a ring shape that entirely surrounds the opening area RA in the first non-display area NDA1. Each of the first and second grooves G1 and G2 may have a diameter greater than that of the opening area RA, and the first and second grooves G1 and G2 may be spaced apart from each other by a predetermined interval.

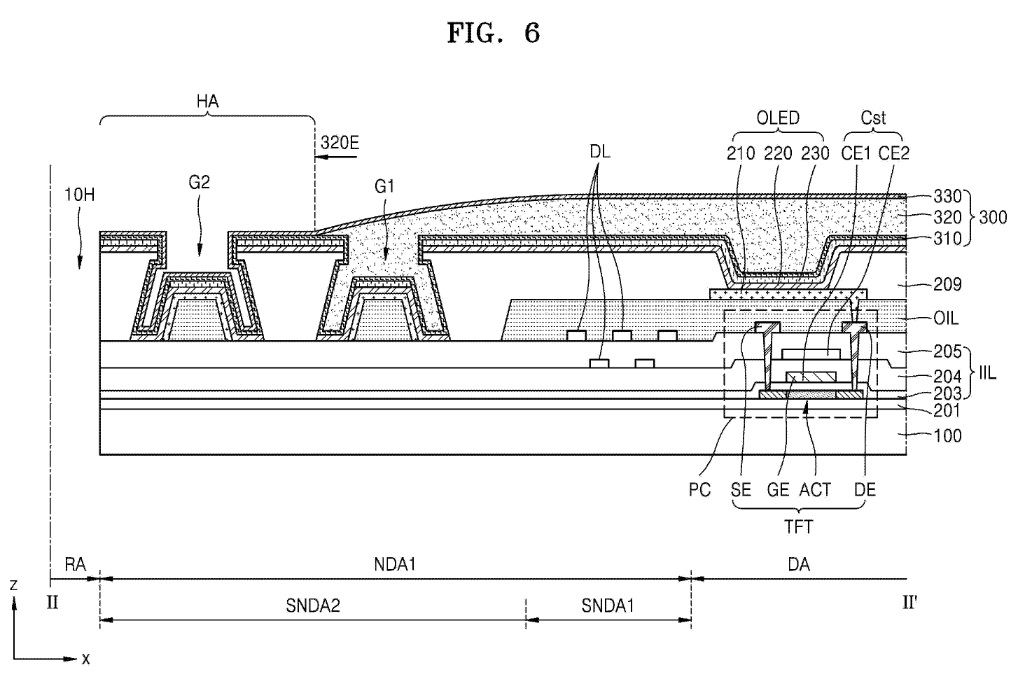

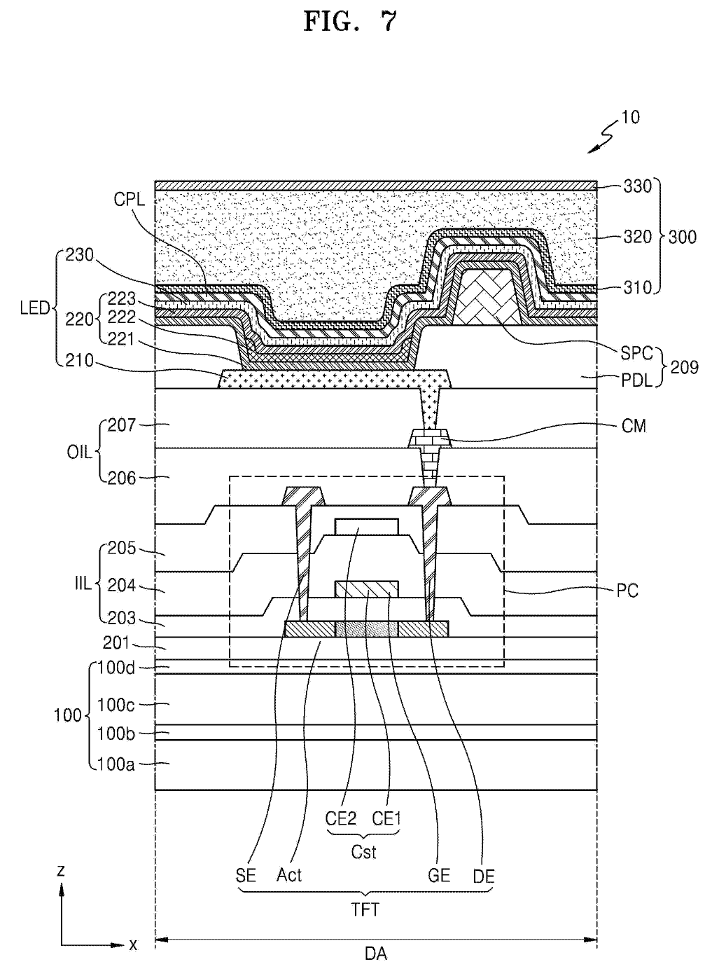

FIG. 6 is a cross-sectional view schematically illustrating an example of a cross section taken along line II-II′ of FIG. 5, and FIG. 7 is a cross-sectional view illustrating an example of the display area shown in FIG. 6.

Referring to FIGS. 6 and 7, the display panel 10 may include the substrate 100, the organic light-emitting diode OLED, and the pixel circuit PC electrically connected to the organic light-emitting diode OLED. For example, the pixel circuit PC and the organic light-emitting diode OLED may be disposed in the display area DA on the substrate 100.

As described above, the substrate may have a multilayer structure including a layer containing a polymer resin and an inorganic layer (not shown). For example, the substrate 100 may include a first base layer 100a, a first barrier layer 100b, a second base layer 100c, and a second barrier layer 100d that are sequentially stacked in a thickness direction (e.g., in a z-axis direction).

At least one of the first base layer 100a and the second base layer 100c may include the above-described polymer resin. The first barrier layer 100b and the second barrier layer 100d may include an inorganic insulating material such as silicon nitride, silicon oxide, or silicon oxynitride.

A buffer layer 201 may be disposed on the substrate 100. The buffer layer 201 may reduce or block the penetration of foreign substances, moisture, or external air from below the substrate 100, and may provide a flat surface on the substrate 100. The buffer layer 201 may include an inorganic material, an organic material, or an organic-inorganic composite material such as silicon nitride, silicon oxide, or silicon oxynitride, and may have a single-layer or multilayer structure of an inorganic material and an organic material.

The pixel circuit PC may be disposed on the buffer layer 201. The pixel circuit PC may include a thin-film transistor TFT and a storage capacitor Cst. The thin-film transistor TFT may include a semiconductor layer Act, a gate electrode GE, a source electrode SE, and a drain electrode DE, and the storage capacitor Cst may include a lower electrode CE1 and an upper electrode CE2.

The semiconductor layer Act may be disposed on the buffer layer 201. The semiconductor layer Act may include polysilicon. Alternatively, the semiconductor layer Act may include amorphous silicon, an oxide semiconductor, an organic semiconductor, or the like. The semiconductor layer Act may include a channel region, and drain and source regions respectively disposed on opposite sides of the channel region.

The gate electrode GE may be disposed on the semiconductor layer Act. The gate electrode GE may overlap the channel region of the semiconductor layer Act. The gate electrode GE may include a low-resistance metal material. The gate electrode GE may include a conductive material including molybdenum (Mo), aluminum (Al), copper (Cu), titanium (Ti), or the like, and may be formed as a single layer or a multilayer including material(s) described above.

A first gate insulating layer 203 may be disposed between the semiconductor layer Act and the gate electrode GE. The first gate insulating layer 203 may include an inorganic insulating material such as silicon oxide, silicon nitride, silicon oxynitride, aluminum oxide, titanium oxide, tantalum oxide, hafnium oxide, or zinc oxide. The first gate insulating layer 203 may be a single layer or a multilayer including the above-described inorganic insulating material.

A second gate insulating layer 204 may be disposed on the gate electrode GE so as to cover the gate electrode GE. The second gate insulating layer 204 may include an inorganic insulating material such as silicon oxide, silicon nitride, silicon oxynitride, aluminum oxide, titanium oxide, tantalum oxide, hafnium oxide, or zinc oxide. The second gate insulating layer 204 may be a single layer or a multilayer including the above-described inorganic insulating material.

The upper electrode CE2 of the storage capacitor Cst may be disposed on the second gate insulating layer 204. At least a portion of the upper electrode CE2 may overlap the gate electrode GE, and the gate electrode GE may function as the lower electrode CE1 of the storage capacitor Cst. For example, the gate electrode GE may be integrally formed with the lower electrode CE1.

The upper electrode CE2 may include a conductive material including molybdenum (Mo), aluminum (Al), copper (Cu), titanium (Ti), or the like, and may be formed as a single layer or a multilayer including material(s) described above.

An interlayer insulating layer 205 may be disposed on the upper electrode CE2. The interlayer insulating layer 205 may be formed to cover the upper electrode CE2 and may include silicon oxide, silicon nitride, silicon oxynitride, or the like. The interlayer insulating layer 205 may be a single layer or a multilayer including the above-described inorganic insulating material. In the present aspect, an inorganic insulating layer IIL includes the first gate insulating layer 203, the second gate insulating layer 204, and the interlayer insulating layer 205.

The source electrode SE and the drain electrode DE are disposed on the interlayer insulating layer 205. The source electrode SE and the drain electrode DE may each include a conductive material including molybdenum (Mo), aluminum (Al), copper (Cu), titanium (Ti), or the like, and may be formed as a single layer or a multilayer including material(s) described above. For example, the source electrode SE and the drain electrode DE may each be formed as a multilayer structure of Ti/Al/Ti. In some aspects, the source electrode SE or the drain electrode DE may be omitted. For example, adjacent thin-film transistors TFTs may share the source region or the drain region of the semiconductor layer Act, and the source region or the drain region may function as the source electrode SE or the drain electrode DE.

A first planarization layer 206 and a second planarization layer 207 may be sequentially disposed to cover the source electrode SE and the drain electrode DE. The first planarization layer 206 and the second planarization layer 207 may have a flat upper surface so that the pixel electrode 210 disposed thereon can be formed flat.

The first planarization layer 206 and the second planarization layer 207 may each include materials such as benzocyclobutene (BCB), polyimide, hexamethyldisiloxane (HMDSO), polymethylmethacrylate (PMMA), polystyrene (PS), general-purpose polymers, polymer derivatives having phenol groups, acrylic polymers, imide-based polymers, arylether-based polymers, amide-based polymers, fluorine-based polymers, p-xylene-based polymers, or vinyl alcohol-based polymers. Each of the first planarization layer 206 and the second planarization layer 207 may be a single layer or a multilayer including the above-described organic insulating materials. In the present aspect, an organic insulating layer OIL may include the first planarization layer 206 and the second planarization layer 207.

A connection electrode CM may be disposed between the first planarization layer 206 and the second planarization layer 207. The connection electrode CM may be connected to the drain electrode DE of the thin-film transistor TFT through a contact hole defined in the first planarization layer 206. The connection electrode CM may include a conductive material including molybdenum (Mo), aluminum (Al), copper (Cu), titanium (Ti), or the like, and may be formed as a single layer or a multilayer including material(s) described above.

Although FIG. 7 illustrates an example in which the organic insulating layer OIL includes two organic layers, the present disclosure is not limited thereto. In an aspect, the organic insulating layer OIL may include only one organic layer. In one or more aspects, the connection electrode CM may be omitted, and the pixel electrode 210 of the organic light-emitting diode OLED may be directly connected to the drain electrode DE of the thin-film transistor TFT. In another aspect, the organic insulating layer OIL may include three or more organic layers. In some aspects, the connection electrode CM may be provided between respective organic layers to electrically connect the pixel electrode 210 of the organic light-emitting diode OLED to the drain electrode DE of the thin-film transistor TFT.

The organic light-emitting diode OLED may be disposed on the second planarization layer 207. The organic light-emitting diode OLED may include the pixel electrode 210, a counter electrode 230, and an intermediate layer 220 positioned between the pixel electrode 210 and the counter electrode 230.

The pixel electrode 210 may be disposed on the second planarization layer 207. The pixel electrode 210 may be electrically connected to the connection electrode CM through a contact hole defined in the second planarization layer 207. The pixel electrode 210 may include a conductive oxide such as indium tin oxide (ITO), indium zinc oxide (IZO), zinc oxide (ZnO), indium oxide (In₂O₃), indium gallium oxide (IGO), or aluminum zinc oxide (AZO). The pixel electrode 210 may include a reflective film including silver (Ag), magnesium (Mg), aluminum (Al), platinum (Pt), palladium (Pd), gold (Au), nickel (Ni), neodymium (Nd), iridium (Ir), chromium (Cr), or a compound thereof. For example, the pixel electrode 210 may have a structure in which films including ITO, IZO, ZnO, or In₂O₃ are disposed above and/or below the above-described reflective film. For example, the pixel electrode 210 may have a stacked structure of ITO/Ag/ITO.

The organic pattern layer 209 may include an opening that exposes an upper surface of the pixel electrode 210, and may cover an edge of the pixel electrode 210. The organic pattern layer 209 may include an inorganic insulating material. For example, the organic pattern layer 209 may include silicon oxide and/or silicon nitride, and may be formed as a single layer or a multilayer. For example, the organic pattern layer 209 may include a pixel defining layer PDL and a spacer SPC disposed on the pixel defining layer PDL.

The pixel defining layer PDL may be disposed on the second planarization layer 207 so as to cover the edge of the pixel electrode 210. The pixel defining layer PDL may include a pixel opening that exposes a central portion of the pixel electrode 210. The pixel opening defines an emission region of the organic light-emitting diode OLED, that is, the size and shape of the pixel.

The pixel defining layer PDL may serve to prevent arc discharge from occurring at the edge of the pixel electrode 210 by increasing a distance between the edge of the pixel electrode 210 and the counter electrode 230 disposed above the pixel electrode 210. The pixel defining layer PDL may include an organic insulating material such as polyimide, polyamide, acrylic resin, benzocyclobutene, hexamethyldisiloxane (HMDSO), or phenolic resin, and may be formed by a method such as spin coating.

The pixel defining layer PDL may be formed in black. The pixel defining layer PDL may include a light-blocking material and may be formed in black. The light-blocking material may include carbon black, carbon nanotubes, a resin or paste including black dye, metal particles such as nickel (Ni), aluminum (Al), molybdenum (Mo), or alloys thereof, metal oxide particles (e.g., chromium oxide), or metal nitride particles (e.g., chromium nitride). When the pixel defining layer PDL includes a light-blocking material, the pixel defining layer PDL may reduce edge reflection caused by metal structures disposed below the pixel defining layer PDL.

The spacer SPC may be disposed on the pixel defining layer PDL. The spacer SPC may include an organic insulating material such as polyimide, polyamide, acrylic resin, benzocyclobutene, hexamethyldisiloxane (HMDSO), or phenolic resin.

In an aspect, the spacer SPC may include the same material as the pixel defining layer PDL. The spacer SPC and the pixel defining layer PDL may be formed simultaneously using a half-tone mask or the like.

The intermediate layer 220 may include a light-emitting layer 222 disposed corresponding to the pixel opening of the pixel defining layer PDL. The light-emitting layer 222 may include a polymer material or a low-molecular-weight material, and may emit light of a red, green, blue, or white color.

A first functional layer 221 and/or a second functional layer 223 may be disposed below and/or above the light-emitting layer 222, respectively. In an aspect, unlike the light-emitting layer 222, which may be patterned and disposed for each pixel, the first functional layer 221 and the second functional layer 223 may be integrally provided over the entire display area DA.

The first functional layer 221 may be a single layer or a multilayer. For example, the first functional layer 221 may include a hole injection layer and/or a hole transport layer. The second functional layer 223 may be optionally disposed. The second functional layer 223 may be a single layer or a multilayer.

The second functional layer 223 may include an electron transport layer and/or an electron injection layer. In some aspects, at least one of the hole injection layer, the hole transport layer, the electron transport layer, and the electron injection layer may be omitted.

The intermediate layer 220 may have a single-stack structure including a single light-emitting layer, or a tandem structure having a multi-stack structure including a plurality of light-emitting layers. In the case of a tandem structure, a charge generation layer may be disposed between the plurality of stacks.

Among the plurality of layers constituting the intermediate layer 220, some layers, such as the functional layer(s), may be disposed not only in the display area DA but also in the first non-display area NDA1, and may be disconnected in the first non-display area NDA1 by the first and second grooves G1 and G2, which will be described below.

The counter electrode 230 may be disposed to face the pixel electrode 210 with the intermediate layer 220 positioned therebetween. The counter electrode 230 may be formed of a conductive material having a low work function. For example, the counter electrode 230 may include a (semi-)transparent layer including silver (Ag), magnesium (Mg), aluminum (Al), platinum (Pt), palladium (Pd), gold (Au), nickel (Ni), neodymium (Nd), iridium (Ir), chromium (Cr), lithium (Li), calcium (Ca), or an alloy thereof. Alternatively, the counter electrode 230 may further include a layer, such as ITO, IZO, ZnO, or In₂O₃, on the (semi-)transparent layer including the material(s) described above.

In an aspect, a capping layer CPL may be disposed on the counter electrode 230. The capping layer CPL may improve light emission efficiency of the organic light-emitting diode OLED based on the principle of constructive interference. The capping layer CPL may be an organic capping layer including an organic material, an inorganic capping layer including an inorganic material, or a composite capping layer including both an organic material and an inorganic material.

The thin-film encapsulation layer 300 may be disposed on the capping layer CPL so as to cover the organic light-emitting diode OLED.

The thin-film encapsulation layer 300 may include at least one organic encapsulation layer and at least one inorganic encapsulation layer. Although FIG. 7 illustrates an example in which the thin-film encapsulation layer 300 includes first and second inorganic encapsulation layers 310 and 330 and an organic encapsulation layer 320 positioned therebetween, the scope of the present disclosure is not limited thereto, and the stacking order and number of layers may be changed.

The first and second inorganic encapsulation layers 310 and 330 may include one or more inorganic insulating materials such as aluminum oxide, titanium oxide, tantalum oxide, hafnium oxide, zinc oxide, silicon oxide, silicon nitride, or silicon oxynitride, and may be formed by a process such as chemical vapor deposition (CVD). The organic encapsulation layer 320 may include a polymer-based material. Examples of the polymer-based material may include acrylic resin, epoxy resin, polyimide, polyethylene, and the like.

Referring to the first non-display area NDA1 of FIG. 6, the first non-display area NDA1 may include a first sub-non-display area SNDA1 that is relatively far from the opening area RA, and a second sub-non-display area SNDA2 that is relatively close to the opening area RA.

The first sub-non-display area SNDA1 may be an area across which signal lines pass, and the data lines DL illustrated in FIG. 6 correspond to the data lines that detour the opening area RA, as described with reference to FIG. 5.

The data lines DL may be alternately disposed with an insulating layer positioned therebetween. By disposing adjacent data lines DL above and below an insulating layer (e.g., the interlayer insulating layer 205), a distance (pitch) between the adjacent data lines DL may be reduced, thereby allowing a width of the first non-display area NDA1 to be reduced. Although only the data lines DL are illustrated in the first sub-non-display area SNDA1 in FIG. 6, the scan lines that detour the opening area RA, as previously described with reference to FIG. 5, may also be located in the first sub-non-display area SNDA1.

The second sub-non-display area SNDA2 may be an area for preventing lateral moisture permeation that proceeds in a lateral direction of the display element layer 200 (in the x-direction) through the opening 10H, and the first and second grooves G1 and G2, which will be described below, may be disposed in the second sub-non-display area SNDA2.

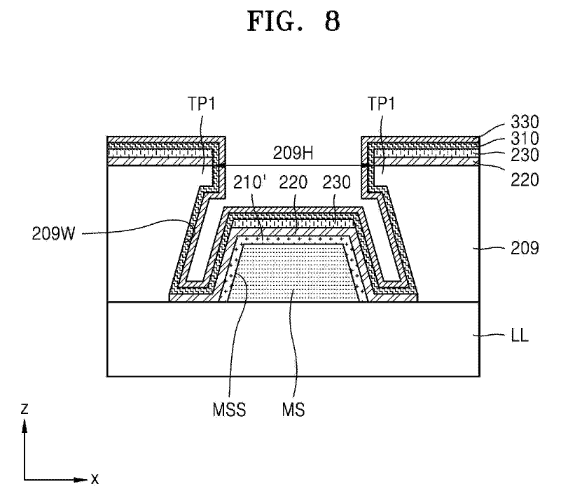

FIG. 8 is an enlarged cross-sectional view illustrating the second groove G2 of FIG. 6.

Referring again to FIGS. 5 and 6, the display panel 10 may include the substrate 100 and the first and second grooves G1 and G2 formed on the substrate 100. For example, the first groove G1 and the second groove G2 may be disposed in the first non-display area NDA1 of the substrate 100. The second groove G2 may be disposed closer to the opening area RA than the first groove G1. In some aspects, grooves in addition to the first groove G1 and the second groove G2 may also be disposed. Since the first groove G1 and the second groove G2 are substantially the same within the corresponding range, a detailed description will be provided here mainly with respect to the second groove G2, and differences between the first groove G1 and the second groove G2 will be described below in detail.

Referring to FIG. 8, the second groove G2 may be formed in the organic pattern layer 209. Here, the organic pattern layer 209 may include at least one of the pixel defining layer PDL and the spacer SPC, as described above.

In FIG. 8, the organic pattern layer 209 is illustrated as being disposed on a lower layer LL. Here, the lower layer LL schematically represents a multilayer film including the substrate 100 and the inorganic insulating layer IIL.

In some aspects, the organic pattern layer 209 may be disposed on the organic insulating layer OIL that forms a mesa structure MS. The mesa structure MS will be described in detail below.

The second groove G2 is defined by a first hole 209H of the organic pattern layer 209. Here, the first hole 209H is a space formed to have a predetermined depth in a thickness direction of the organic pattern layer 209, and may be formed by partially removing the organic pattern layer 209.

In other words, the second groove G2 refers to a recessed portion formed by removing a portion of a layer in the thickness direction from an upper surface of the layer. In a plan view, the hole or groove of the organic pattern layer 209 may have a closed-loop shape surrounding the opening area RA.

The organic pattern layer 209 according to an aspect of the present disclosure may include a positive-type photoresist. For example, the organic pattern layer 209 may include a novolac resin, a phenol-based resin, polyhydroxystyrene (PHS), diazonaphthoquinone (DNQ), triphenylsulfonium triflate (TPS-Tf), or a combination thereof.

In some aspects, the organic pattern layer 209 in which the second groove G2 is formed may include the same material as the organic pattern layer 209 in the display area DA. For example, the organic pattern layer 209 may include the same material as the pixel defining layer PDL or the same material as the spacer SPC.

That is, when the pixel defining layer PDL is disposed in the display area DA, the pixel defining layer PDL may also be disposed in the first non-display area NDA1. For example, the layer for forming the second groove G2 may be formed of the same layer as the pixel defining layer PDL. Alternatively, when the spacer SPC is disposed in the display area DA, the spacer SPC may also be disposed in the first non-display area NDA1. For example, the layer for forming the second groove G2 may be formed of the same layer as the spacer SPC.

In an aspect, the organic pattern layer 209 may include the same material as the pixel defining layer PDL and the spacer SPC. That is, as illustrated in FIG. 7, the organic pattern layer 209 may have a multilayer film structure including the pixel defining layer PDL and the spacer SPC.

The organic pattern layer 209 may include first protruding tips TP1 that protrude toward the center of the first hole 209H. Each of the first protruding tips TP1 of the organic pattern layer 209 may be a portion having a predetermined thickness from an upper surface of the organic pattern layer 209. For example, each of the first protruding tips TP1 may be a portion extending in a direction toward the center of the second groove G2 from the upper surface of the organic pattern layer 209. Each of the first protruding tips TP1 may serve as a kind of eave and may protrude from a side surface of the organic pattern layer 209, which defines an inner side surface of the first groove G1, toward the center of the second groove G2. A width of the first hole 209H of the organic pattern layer 209 below the first protruding tips TP1 may be greater than a width of the first hole 209H between the first protruding tips TP1. In some aspects, the organic pattern layer 209 may have an undercut structure in which a lower portion is wider than an upper portion.

As shown in FIG. 6, the intermediate layer 220 and the counter electrode 230 are formed on the substrate 100 on which the second groove G2 is disposed. Similar to the counter electrode 230, the intermediate layer 220 may be integrally formed in both the display area DA and the first non-display area NDA1. However, since the second groove G2 is disposed in the first non-display area NDA1, the intermediate layer 220 may be disconnected around the second groove G2. Similarly, the counter electrode 230 may also be disconnected around the second groove G2.

Specifically, a portion of the intermediate layer 220 located adjacent to the lower layer LL (that is, the portion of the intermediate layer 220 located on a bottom surface of the second groove G2) may be spaced apart and separated from a portion of the intermediate layer 220 located on the first protruding tip TP1. Similarly, a portion of the counter electrode 230 located adjacent to the lower layer LL may be spaced apart and separated from a portion of the counter electrode 230 located on the first protruding tip TP1.

A layer including an organic material in the display device 1 may serve as a moisture permeation path through which moisture can travel. Moisture and/or external air may travel toward the display area DA (see FIG. 5) through a side surface of the opening 10H (see FIG. 2A) of the display panel 10, and continuously formed organic material layers, such as the first functional layer 221 and the second functional layer 223, may serve as penetration paths for the moisture.

However, by forming organic material layers, such as the intermediate layer 220, in both the display area DA and the first non-display area NDA1, and separating or disconnecting the organic material layer around the second groove G2, the formation of the above-described moisture permeation paths may be prevented. The counter electrode 230, which is formed by a thermal evaporation method, may also be separated or disconnected around the second groove G2 similarly to the organic material layer, such as the intermediate layer 220.

Specifically, as the first functional layer 221 and the second functional layer 223 are each disconnected by the second groove G2, the progression of moisture or the like toward the display area DA (see FIG. 5) may be reduced or prevented.

Referring again to FIG. 8, the second groove G2 may include the mesa structure MS disposed within the first hole 209H and a reflective layer 210′ disposed on the mesa structure MS.

The mesa structure MS may be disposed at a position at which the second groove G2 is to be formed in the first non-display area NDA1. For example, the second groove G2 may be formed along a position at which the mesa structure MS is formed.

The mesa structure MS may include the same material as the organic insulating layer OIL disposed in the display area DA. That is, the organic insulating layer OIL may be integrally formed across the display area DA and the first non-display area NDA1. In addition, the mesa structure MS may be formed by partially removing the organic insulating layer OIL. For example, the mesa structure MS may be formed by etching or ashing a portion of the organic insulating layer OIL.

The mesa structure MS may be a portion protruding upward from the lower layer LL and may include an upper surface and side surfaces. For example, the mesa structure MS may have a shape protruding in a stacking direction from the organic insulating layer OIL, and side surfaces of the protruding structure may include inclined surfaces MSS. Here, the inclined surfaces MSS may be formed to be inclined such that a width of the mesa structure MS becomes narrower in an upward direction.

In an aspect, the reflective layer 210′ may cover the upper surface and side surfaces of the mesa structure MS. The reflective layer 210′ may include a metal material having high reflectivity, such as silver (Ag) or aluminum (Al).

In an aspect, the reflective layer 210′ may include the same material as the pixel electrode 210. For example, the reflective layer 210′ may be integrally formed across the display area DA and the first non-display area NDA1.

The reflective layer 210′ may include a conductive oxide such as indium tin oxide (ITO), indium zinc oxide (IZO), zinc oxide (ZnO), indium oxide (In₂O₃), indium gallium oxide (IGO), or aluminum zinc oxide (AZO). The reflective layer 210′ may also include a metal film including silver (Ag), magnesium (Mg), aluminum (Al), platinum (Pt), palladium (Pd), gold (Au), nickel (Ni), neodymium (Nd), iridium (Ir), chromium (Cr), or a compound thereof. For example, the reflective layer 210′ may have a structure in which a film formed of ITO, IZO, ZnO, or In₂O₃ is disposed above and/or below the above-described metal film. In such aspects, the reflective layer 210′ may have a stacked structure of ITO/Ag/ITO.

The organic pattern layer 209 may be disposed on the organic insulating layer OIL. The organic pattern layer 209 may be formed to be spaced apart from the mesa structure MS. The first hole 209H of the organic pattern layer 209 may be symmetrically formed with respect to the mesa structure MS.

In a cross-sectional view, inner sidewalls 209W of the organic pattern layer 209 may be disposed adjacent to the side surfaces of the mesa structure MS, and the mesa structure MS may be disposed between the inner sidewalls 209W of the organic pattern layer 209.

In some aspects, the organic pattern layer 209 may include the inner sidewalls 209W formed on opposite sides of the mesa structure MS, and the inner sidewalls 209W may be formed to be spaced apart from the reflective layer 210′.

The intermediate layer 220 may be disposed on the upper surface of the organic pattern layer 209 and on the reflective layer 210′ surrounding the mesa structure MS. The intermediate layer 220 may also be disposed on the bottom surface of the second groove G2 between the mesa structure MS and the inner sidewalls 209W of the organic pattern layer 209. That is, the intermediate layer 220 may also be disposed on an upper surface of the lower layer LL.

However, as described above, since the organic pattern layer 209 forms an undercut structure including the first protruding tips TP1, the intermediate layer 220 disposed on the upper surface of the organic pattern layer 209 and the intermediate layer 220 disposed on the bottom surface of the second groove G2 may be disconnected from each other. Accordingly, as the thin-film encapsulation layer 300 is disposed after the intermediate layer 220 is disposed, the disconnected portions of the intermediate layer 220 may be covered by the thin-film encapsulation layer 300.

Specifically, the counter electrode 230 may be disposed on the intermediate layer 220, and a first inorganic encapsulation layer 310 may be disposed on the counter electrode 230.

Unlike the intermediate layer 220 and the counter electrode 230, since the first inorganic encapsulation layer 310 may have relatively superior step coverage and, as shown in FIG. 8, the first inorganic encapsulation layer 310 may cover an entire inner side surface of the second groove G2. The first inorganic encapsulation layer 310 may be continuously formed without being disconnected by the undercut structure of the second groove G2. For example, the first inorganic encapsulation layer 310 may cover side surfaces of the first protruding tips TP1, the inner sidewalls 209W of the organic pattern layer 209, and the bottom surface of the second groove G2. In some aspects, the first inorganic encapsulation layer 310 may be in direct contact with the upper surface of the lower layer LL exposed through the second groove G2.

As the organic layer, i.e., the organic insulating layer OIL (e.g., the first planarization layer 206 and the second planarization layer 207), is disconnected by the second groove G2, lateral moisture permeation (in the x-direction) may be prevented. In addition, since the first inorganic encapsulation layer 310 comes into direct contact with the interlayer insulating layer 205, which is the inorganic insulating layer IIL exposed through the second groove G2, all of the layer(s) including an organic material are covered, thereby blocking lateral moisture permeation through the layer(s) including an organic material.

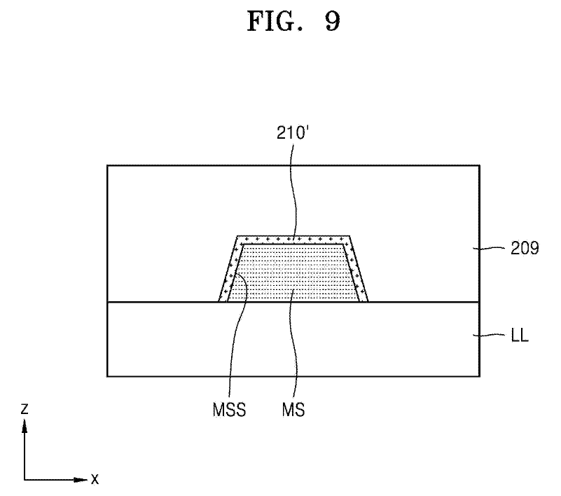

FIGS. 9 to 12 are cross-sectional views schematically illustrating sequential steps of a method of manufacturing the display panel 10 according to an aspect of the present disclosure.

Referring to FIG. 9, an organic insulating layer OIL may be disposed on a lower layer LL including the substrate 100 and the inorganic insulating layer IIL, which are described above. A portion of the organic insulating layer OIL may be removed through a process such as etching or ashing, thereby forming a mesa structure MS from the organic insulating layer OIL.

The mesa structure MS may be formed at a position at which a second groove G2 is to be formed in a first non-display area NDA1.

A reflective layer 210′ may be disposed on the mesa structure MS. In some aspects, the reflective layer 210′ may cover an upper surface and side surfaces of the mesa structure MS.

An organic pattern layer 209 may be disposed on the lower layer LL and on the reflective layer 210′. When the organic insulating layer OIL remains not only on the mesa structure MS but also on the upper surface of the lower layer LL, the organic pattern layer 209 may also be disposed on the organic insulating layer OIL. The organic pattern layer 209 may cover both the mesa structure MS protruding from the lower layer LL and the reflective layer 210′ disposed on the mesa structure MS.

As described above, the organic pattern layer 209 may include a positive-type photoresist. The organic pattern layer 209 may be uniformly applied through a spin coating method and may be stabilized by evaporating a solvent through a baking process.

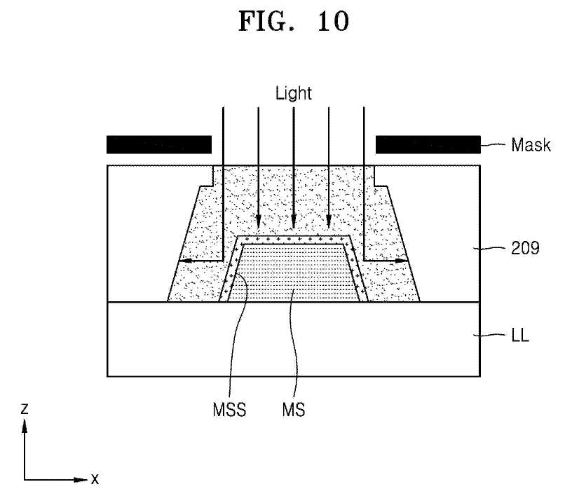

Thereafter, as shown in FIG. 10, an exposure process may be performed by irradiating light onto the organic pattern layer 209.

Light may be irradiated, using a photomask, onto a position at which the second groove G2 is to be formed. Specifically, light may be irradiated onto the organic pattern layer 209 covering the portion in which the mesa structure MS is formed. That is, a portion of the organic pattern layer 209 overlapping the mesa structure MS may be exposed.

At this time, the light may be reflected by the mesa structure MS and the reflective layer 210′ and reach inner side surfaces of the organic pattern layer 209. That is, the light may also be irradiated onto regions other than those defined by the photomask pattern.

Specifically, inclined surfaces MSS present on the side surfaces of the mesa structure MS may reflect the irradiated light in a lateral direction so that inner sidewalls 209W of the organic pattern layer 209 are additionally exposed.

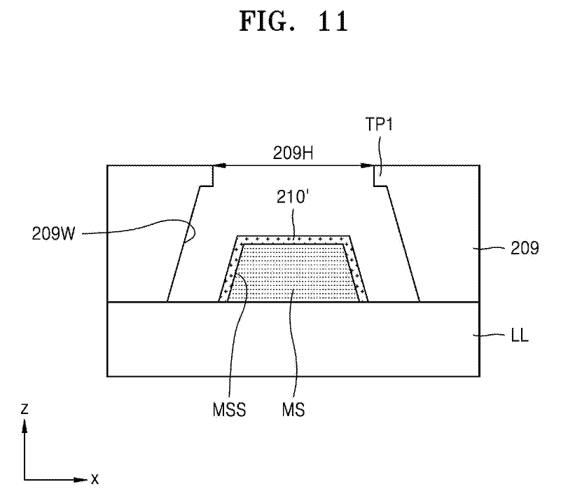

FIG. 11 illustrates a state in which the exposed portions of the organic pattern layer 209 is removed through a developing process. As the inner sidewalls 209W of the organic pattern layer 209 are exposed during the exposure process, the exposed portions of the inner sidewall 209W may be removed during the developing process, thereby forming protruding tips. That is, a first hole 209H may be formed such that a width thereof is greater at a lower portion than at an upper portion.

Accordingly, by including the mesa structure MS, the display panel 10 according to an aspect of the present disclosure may induce a notching phenomenon, which in turn may result in the formation of the above-described undercut structure. Even when the organic pattern layer 209 is formed as a single layer, an undercut structure such as first protruding tips TP1 may be formed. That is, according to an aspect of the present disclosure, a groove having an undercut structure may be formed within a single layer.

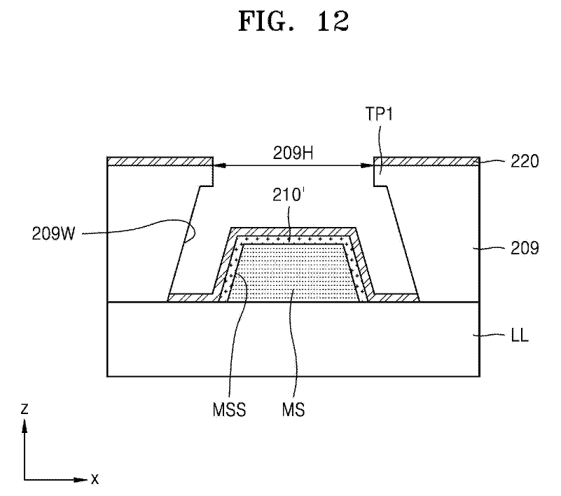

FIG. 12 illustrates a state in which an intermediate layer 220 is formed within the second groove G2 having an undercut structure. When the intermediate layer 220 is formed on the organic pattern layer 209 having such an undercut structure, the intermediate layer 220 disposed on an upper surface of the organic pattern layer 209 and the intermediate layer 220 disposed on a bottom surface of the second groove G2 may be disconnected from each other.

Although the above description focuses on the structure of the second groove G2, the first groove G1 may also have the same structure. However, an organic encapsulation layer 320 may be filled in the first groove G1 on the first inorganic encapsulation layer 310. In addition, a second inorganic encapsulation layer 330 may be disposed on the organic encapsulation layer 320.

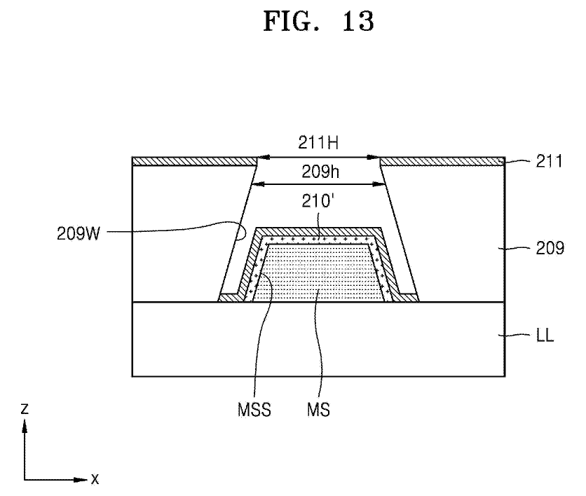

FIGS. 13 to 15 are cross-sectional views schematically illustrating sequential steps of a method of manufacturing the display panel 10 according to another aspect of the present disclosure.

Referring to FIG. 13, an operation of forming protruding tips may further include forming a metal oxide layer 211 on an organic pattern layer 209 and on a reflective layer 210′.

In one or more aspects, before an intermediate layer 220 is formed in the operation shown in FIG. 11, the metal oxide layer 211 may be formed first.

Here, the metal oxide layer 211 may include a conductive oxide, such as indium tin oxide (ITO), indium zinc oxide (IZO), zinc oxide (ZnO), indium oxide (In₂O₃), indium gallium oxide (IGO), or aluminum zinc oxide (AZO).

The metal oxide layer 211 may be disposed on an upper surface of the organic pattern layer 209, on an upper surface of a mesa structure MS, and on a bottom surface of a second groove G2. The metal oxide layer 211 may be formed on an upper surface of the organic pattern layer 209 to form a second hole 211H. The second hole 211H of the metal oxide layer 211 may be formed corresponding to a first hole 209H of the organic pattern layer 209.

The metal oxide layer 211 may be deposited by a sputtering process. After the metal oxide layer 211 is deposited, portions of inner sidewalls 209W of the organic pattern layer 209 may be removed through an ashing process.

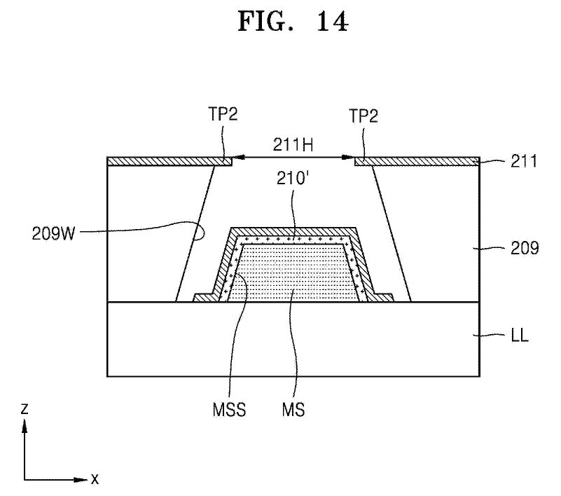

Referring to FIG. 14, second protruding tips TP2 may be formed as portions of the inner sidewalls 209W of the organic pattern layer 209 are removed through the ashing process.

That is, since the metal oxide layer 211 formed on the upper surface of the organic pattern layer 209 remains relatively robust compared to the organic pattern layer 209, when a lower portion of the metal oxide layer 211 is removed, one end portion of the metal oxide layer 211 may be formed to protrude toward the center of the second groove G2.

By additionally including the metal oxide layer 211 on the organic pattern layer 209 in this manner, the second protruding tips TP2 may be formed, thereby complementing the first protruding tips TP1 formed by the organic pattern layer 209 and enabling the formation of an undercut structure for the second groove G2.

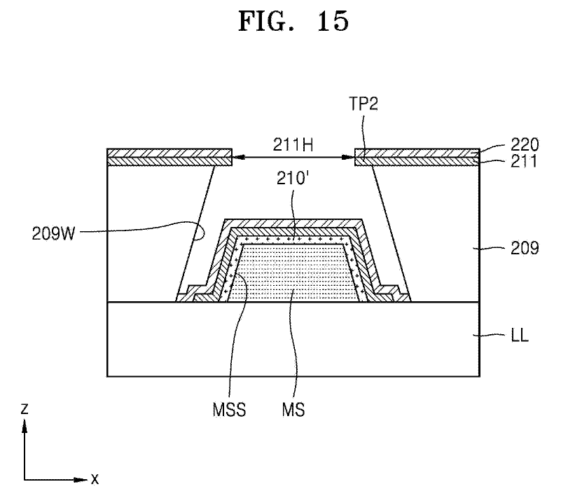

Referring to FIG. 15, the intermediate layer 220 may be disposed on the organic pattern layer 209 and on the mesa structure MS, and may also be disposed on the bottom surface of the second groove G2. However, the intermediate layer 220 may be disconnected by the second groove G2.

With the undercut structure formed by the second protruding tips TP2, a portion of the intermediate layer 220 disposed on the upper surface of the organic pattern layer 209 and a portion of the intermediate layer 220 disposed on the bottom surface of the second groove G2 may be disconnected from each other.

Some operations of the method of manufacturing the display panel 10 according to an aspect of the present disclosure have been described above.

In some aspects, when an undercut structure is formed by ashing the organic insulating layer OIL prior to forming the pixel electrode 210, defects such as air bubbles may occur due to the metal tips during the subsequent coating and drying processes.

According to an aspect of the present disclosure, by performing the operation of forming the protruding tip after forming the pixel electrode 210 and the pixel defining layer PDL, air bubble defects caused by the protruding tip during the coating and drying processes may be prevented.

The display device according to the aspect may be applied to various electronic devices. The electronic device according to an aspect may include the display device described above and may further include modules or devices having additional functions other than the display device.

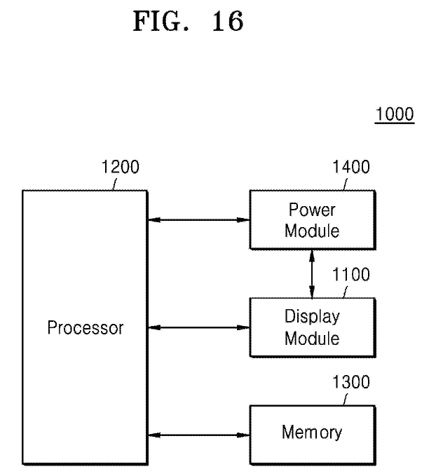

FIG. 16 is a block diagram of an electronic device according to an aspect. Referring to FIG. 16, an electronic device 1000 according to an aspect may include a display module 1100, a processor 1200, a memory 1300, and a power module 1400.

The processor 1200 may include at least one of a central processing unit (CPU), an application processor (AP), a graphic processing unit (GPU), a communication processor (CP), an image signal processor (ISP), and a controller. In an aspect, the processor 1200 may be provided in a form divided into two or more parts from a functional or structural perspective. For example, the processor 1200 may include a main processor in the form of a first driving chip including a central processing unit, and a sub-processor in the form of a second driving chip including a controller configured to receive a video signal from the main processor and process the video signal to comply with interface specifications of the display module 1100.

The memory 1300 may include at least one of a non-volatile memory and a volatile memory. The memory 1300 may store data information necessary for the operation of the processor 1200 or the display module 1100. When the processor 1200 executes an application stored in the memory 1300, a video data signal and/or an input control signal may be transmitted to the display module 1100, and the display module 1100 may process the received signal and output video information through a display screen.

The power module 1400 may include a power supply module, such as a power adapter or a battery device, and a power conversion module that converts power supplied by the power supply module to generate power required for the operation of the electronic device 1000. The power conversion by the power conversion module may include direct current-to-direct current (DC-DC) conversion, alternating current-to-direct current (AC-DC) conversion, or direct current-to-alternating current (DC-AC) conversion, but the present disclosure is not limited thereto.

At least one of the components of the electronic device 1000 described above may be included in the display device according to the aspects described above. In addition, a portion of individual modules included functionally in one module may be included in the display device, while another portion thereof may be provided separately from the display device. For example, the display device may include the display module 1100 and a sub-processor of the processor 1200, while a main processor of the processor 1200, the memory 1300, and the power module 1400 may be provided in the form of separate components within the electronic device 1000, rather than within the display device. As another example, the power module 1400 may be provided within the display device and may supply power to the processor 1200 and the memory 1300 provided within the electronic device 1000, rather than within the display device, without being limited to the above examples.

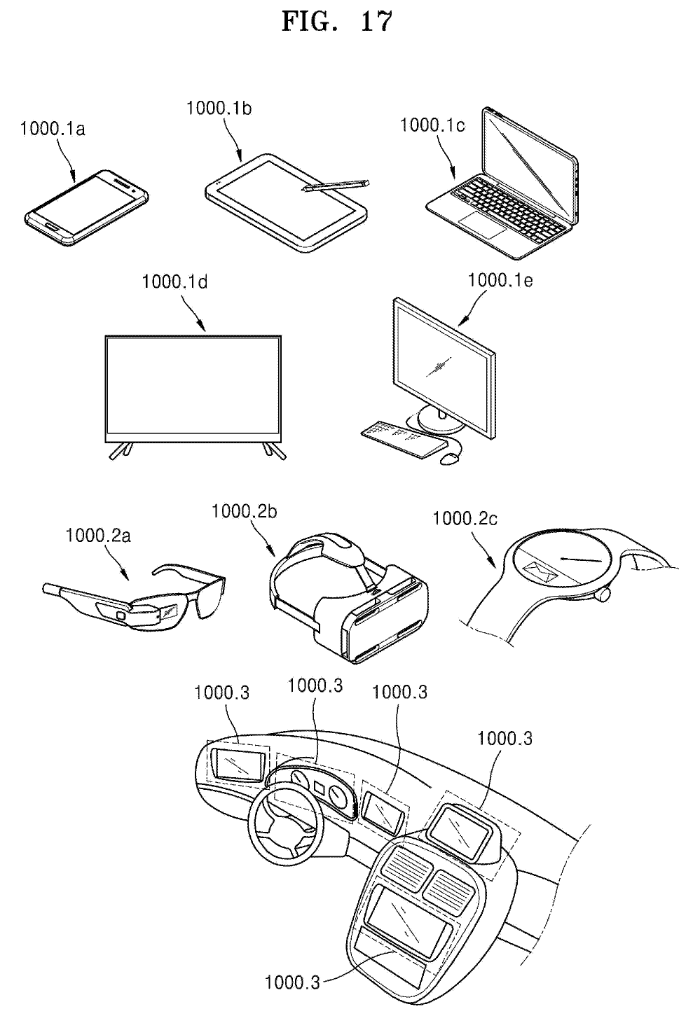

FIG. 17 illustrates schematic views of electronic devices according to various aspects.

Referring to FIG. 17, various electronic devices to which the display device according to the aspects is applied may include not only image display electronic devices such as a smartphone 1000_1a, a tablet personal computer (PC) 1000_1b, a laptop computer 1000_1c, a TV 1000_1d, or a desktop monitor 1000_1e, but also wearable electronic devices including a display module, such as smart glasses 1000_2a, a head-mounted display 1000_2b, or a smart watch 1000_2c, or vehicle electronic devices 1000_3 including a display module, such as an instrument cluster, a center fascia, a center information display (CID) disposed on a dashboard, or a room mirror display.

The electronic devices illustrated in FIG. 17 may include the components illustrated in FIG. 16. For example, the smartphone 1000_1a may include the display module 1100, the processor 1200, the memory 1300, and the power module 1400 illustrated in FIG. 16. The smartphone 1000_1a may further include a communication module and a battery device. Power supplied from the battery device may be converted by the power module 1400 and provided to the processor 1200, the memory 1300, and the display module 1100. In an aspect, the display device applied to the smartphone 1000_1a may include the display module 1100 and may further include the power module 1400. The processor 1200 and the memory 1300 may be provided in the form of chips mounted on a motherboard, which is an external device, but the present disclosure is not limited thereto.

Each of the aspects described above can be implemented independently, but the structures of the aspects can also be combined and applied to other aspects.

According to an aspect of the present disclosure, a display device capable of preventing moisture permeation and an electronic device including the same can be provided.

However, the above effect is exemplary, and the effects of the present disclosure are not limited thereto.

Aspects of the present disclosure have been described with reference to the drawings. It will be understood by those skilled in the art that various modifications and equivalent other aspects may be made. Accordingly, the true technical scope of the present disclosure is defined by the technical spirit of the appended claims.

The particular implementations shown and described herein are illustrative aspects of the present disclosure and are not intended to otherwise limit the scope of the present disclosure in any way. In addition, no item or element is essential to the practice of the present disclosure unless the element is specifically described as “essential” or “critical.”

The use of the terms “a” and “an” and “the” and similar referents in the context of describing the present disclosure (especially in the context of the following claims) are to be construed to cover both the singular and the plural.

Further, recitation of ranges of values herein are merely intended to serve as a shorthand method of referring individually to each separate value falling within the range, unless otherwise indicated herein, and each separate value is incorporated into the specification as if it were individually recited herein. Finally, operations of all methods described herein can be performed in any suitable order unless otherwise indicated herein or otherwise clearly contradicted by context. The present disclosure is not necessarily limited to the described order of the operations. The use of any and all examples, or exemplary terms provided herein, is intended merely to better illustrate the aspects and does not pose a limitation on the scope of the aspects unless otherwise claimed. In addition, it would be apparent to those of ordinary skill in the art that various modifications and changes may be easily made without departing from the scope and spirit of the present disclosure.

What is claimed is:

1. A display device comprising:
a substrate including an open area, a display area at least partially surrounding the open area, and a first non-display area between the open area and the display area;
a plurality of display elements in the display area, each display element of the plurality of display elements including a pixel electrode, a counter electrode, and an intermediate layer between the pixel electrode and the counter electrode;
an organic layer in the first non-display area; and
a first groove surrounding the open area, wherein the first groove comprises a first hole in the organic layer,
wherein the first groove includes:
a mesa structure within the first hole; and
a reflective layer on the mesa structure.

2. The display device of claim 1, wherein the mesa structure protrudes from the substrate in a first direction, wherein the substrate and the organic layer are stacked in the first direction, and wherein the mesa structure includes an upper surface and side surfaces, and the upper surface and the side surfaces are covered with the reflective layer.

3. The display device of claim 2, wherein the mesa structure includes inclined surfaces configured such that a width of the mesa structure becomes narrower in the first direction.

4. The display device of claim 1, wherein the mesa structure includes a same material as an organic insulating layer in the display area.

5. The display device of claim 1, wherein
the organic layer includes inner sidewalls on opposite sides of the mesa structure, and
the inner sidewalls are spaced apart from the reflective layer.

6. The display device of claim 1, wherein the organic layer includes a positive-type photoresist.

7. The display device of claim 1, wherein the organic layer includes first protruding tips that protrude toward a center of the first hole.

8. The display device of claim 1, wherein the reflective layer and the pixel electrode include a same material.

9. The display device of claim 1, wherein the intermediate layer comprises a plurality of layers and at least one layer of the plurality of layers included in the intermediate layer is disconnected by the first groove.

10. The display device of claim 1, wherein the intermediate layer is on an upper surface of the organic layer and on the reflective layer.

11. The display device of claim 1, further comprising a metal oxide layer on the reflective layer and on the organic layer.

12. The display device of claim 11, wherein the metal oxide layer includes a second hole overlapping the first hole.

13. The display device of claim 12, wherein the metal oxide layer includes second protruding tips that protrude toward a center of the second hole.

14. A method of manufacturing a display device, the method comprising:
forming a circuit layer including an inorganic insulating layer on a substrate, the substrate including an open area, a display area at least partially surrounding the open area, and a first non-display area between the open area and the display area;
forming an organic insulating layer on the inorganic insulating layer;
forming a mesa structure by removing at least a portion of the organic insulating layer in the first non-display area;
forming a reflective layer on the mesa structure;
forming an organic layer on the organic insulating layer and on the reflective layer;
exposing a portion of the organic layer overlapping the mesa structure; and
removing an exposed portion of the organic layer to form protruding tips.

15. The method of claim 14, wherein the organic layer includes a positive-type photoresist.

16. The method of claim 14, wherein the reflective layer includes a same material as a pixel electrode of the display area.

17. The method of claim 14, wherein the exposing of the portion of the organic layer includes exposing inner sidewalls of the organic layer adjacent to the mesa structure using light reflected from side surfaces of the mesa structure.

18. The method of claim 14, wherein the method further comprises forming a metal oxide layer on the organic layer and on the reflective layer.

19. The method of claim 14, wherein the method further comprises forming second protruding tips from a metal oxide layer disposed on the organic layer, by partially removing inner sidewalls of the organic layer through an ashing process.

20. An electronic device comprising:
an input module configured to receive commands or data for use in the electronic device from an external source;
a processor configured to process input data received from the input module and to output image data or command data; and
a display device configured to display one or more images from the processor,
wherein the display device includes:
a substrate including an open area, a display area at least partially surrounding the open area, and a first non-display area between the open area and the display area;
a plurality of display elements in the display area, each display element of the plurality of display elements including a pixel electrode, a counter electrode, and an intermediate layer between the pixel electrode and the counter electrode;
an organic layer in the first non-display area; and
a first groove surrounding the open area, wherein the first groove comprises a first hole in the organic layer,
wherein the first groove includes:
a mesa structure within the first hole; and
a reflective layer on the mesa structure.
